(19) United States
(12) Patent Application Publication
(10) Pub. No.: US 2025/0357078 A1
(43) Pub. Date: Nov. 20, 2025

(54) Vacuum arrangement and method

(71) Applicant: VON ARDENNE Asset GmbH & Co. KG, Dresden (DE)

(72) Inventors: Stephan Aulhorn, Radebeul (DE); Steffen Mosshammer, Rabenau (DE)

(21) Appl. No.: 19/206,157

(22) Filed: May 13, 2025

(30) Foreign Application Priority Data
May 14, 2024 (DE) 10 2024 113 393.7

(51) Int. Cl. H01J 37/32

(52) U.S. Cl. CPC H01J 37/32082; H01J 37/32568; H01J 37/32577; H01J 37/32807; H01J 37/32816; H01J 37/3288

(57) ABSTRACT

A vacuum assembly may include a vacuum chamber housing, a transport device for transporting a substrate along a transport path within the vacuum chamber housing, a plasma source having a plasma source housing in which a cavity is provided, an electrode disposed in the vacuum chamber housing and adjacent the plasma source, and a radio frequency transmission device that ohmically couples the plasma source housing to the electrode. The plasma source may be adapted to form a plasma to which the transport path is exposed by the cavity.

### CROSS-REFERENCE TO RELATED APPLICATION

This Patent Application claims priority from German Patent Application No. 10 2024 113 393.7 filed on May 14, 2024 according to 35 U.S.C. § 119, the entire disclosure of which is incorporated herein by reference and for all purposes.

### TECHNICAL FIELD

Various embodiments relate to a vacuum arrangement and a method.

### BACKGROUND

In general, a substrate can be treated (processed) in a vacuum, e.g. coated, so that the chemical and/or physical properties of the substrate can be changed. Various coating processes can be used to coat a substrate, of which physical vapor deposition (PVD) is an established representative. For example, a vacuum coating system can be used to deposit one or more layers on one or more substrates by chemical and/or physical vapor deposition.

For various processes, it can be beneficial to pre-treat or post-treat the substrate using a plasma. To generate the plasma, a plasma source is used which includes a hollow electrode, for example. In this respect, there are generally high demands on the service life of the plasma source in order to reduce maintenance costs.

### SUMMARY

Various embodiments are based on the observation that the service life of the plasma source itself is limited by the service life of individual components that are themselves exposed to the plasma. If the component with the shortest service life fails, the plasma source as a whole often fails as well, which requires maintenance. In this context, it was recognized that this is the case with a so-called grid electrode, with which a plasma source is often equipped when it is sold as a ready-made solution.

A grid electrode is used to limit the spread of the plasma, but still allow the exchange of atoms, electrons and ions through the grid electrode. However, the grid electrode itself is exposed to the plasma and is ablated by the plasma until the grid electrode fails. If the grid electrode fails, the plasma spreads into the vacuum chamber and can damage other components, such as seals, bearings, etc. A compromise must therefore often be made, which either leads to a short maintenance interval in order to replace the grid electrode or accepts the damage to other, sometimes cost-intensive components.

The removal of the grid electrode also stands in the way of high demands on the purity of the plasma, as the components of the grid electrode released by the plasma can reach the substrate and contaminate it, for example. Due to the metallic nature of the grid electrode, this can have a major impact on the properties of the semiconductor product, for example in semiconductor applications.

According to various embodiments, a vacuum arrangement, method and use are provided which inhibit the spatial spread of the plasma, even if the grid electrode includes failed or is not used in the first place. For example, the grid electrode can be omitted (e.g. demounted in advance), which improves the quality of the vacuum.

It was clearly recognized that the function of the grid electrode, which consists of limiting the spatial distribution of the electric field generated by the plasma source to generate the plasma in the vacuum chamber housing, is favored if it is HF-capable. In this context, it was recognized that although the vacuum chamber housing itself is often grounded, its charge exchange with the plasma source is inhibited due to the properties of the electric field, for example its radio frequency.

The current density within an electrical conductor can decrease with increasing frequency (also as the skin effect), so that the impedance of the electrical conductor that opposes the current flow is, to a first approximation, a function of the topography of the electrical conductor. In this case, the current flow occurs approximately primarily on the surface of the electrical conductor, for which a vacuum chamber housing is not usually designed. Therefore, the impedance of the vacuum chamber housing for RF (radio frequency) is usually too high to inhibit the propagation of the plasma by the vacuum chamber housing alone, even if the vacuum chamber housing is earthed.

With this in mind, an RF transmission device is provided by which an electrode is provided in the vacuum chamber housing. The RF transmission device is coupled to the plasma source and promotes a charge exchange between the electrode and the plasma source.

In the following, various examples are described which relate to the aspects described herein and illustrated in the figures.

Example 1 is configured according to one of the appended claims.

Example 2 is configured according to claim 1 and/or a vacuum arrangement, comprising: a vacuum chamber housing; a transport device for transporting a substrate along a transport path within the vacuum chamber housing; a plasma source comprising a plasma source housing in which a cavity is provided, the plasma source being configured to form a plasma by the cavity to which the transport path is exposed; an electrode (also referred to as a chamber electrode) which is arranged in the vacuum chamber housing and (immediately) adjacent (e.g. along the transport path behind) the plasma source; an RF transmission device which connects the plasma source housing ohmically to the plasma source housing and (immediately) to the transport path (e.g. along the transport path behind) the plasma source; an RF transmission device that ohmically couples the plasma source housing to the electrode.

Example 3 is configured according to example 1 or 2, whereby the transmission device is ohmically coupled to the vacuum chamber housing or galvanically separated from the vacuum chamber housing (e.g. by a bearing device).

Example 4 is configured according to example 1 or 3, furthermore having a bearing device by which the electrode is coupled ohmically to the vacuum chamber housing or is mounted galvanically separated from the vacuum chamber housing; or wherein the electrode is attached to the vacuum chamber housing (e.g. a wall thereof) in a flat laying manner.

Example 5 is configured according to one of examples 1 to 4, wherein the plasma source housing is arranged at least partially outside the vacuum chamber housing and/or is mounted on the outside (e.g. on an outer side) of the vacuum chamber housing.

Example 6 is arranged according to one of examples 1 to 5, wherein the transmission device comprises one or more than one electrical line, preferably of which: a first line is arranged in the vacuum chamber housing and/or is provided by an RF-strand (e.g., litz wire), and/or of which a second electrical line is arranged outside the vacuum chamber housing and/or is provided by an RF-strand (also referred to as radio frequency strand) (e.g., litz wire).

Example 7 is arranged according to one of examples 1 to 6, wherein the transmission device comprises one or more than one electrical RF-strand (e.g., litz wire), of which preferably: a first RF-strand (e.g., litz wire) is arranged in the vacuum chamber housing (e.g. providing the first line) and/or a second RF-strand (e.g., litz wire) is arranged outside the vacuum chamber housing (e.g. providing the second line).

Example 8 is configured according to one of examples 1 to 7, wherein the vacuum chamber housing (e.g. a housing wall thereof) includes one or more than one housing opening, of which a vacuum feedthrough of the transmission device is arranged in a first housing opening and/or of which a second housing opening is adjacent to the plasma source (e.g. exposing the cavity).

Example 9 is configured according to one of the examples 1 to 8, wherein the vacuum feedthrough includes a copper rod which extends through the first housing opening and/or which ohmically couples two electrical lines (e.g. RF strands) of the transmission device to one another.

Example 10 is arranged according to any one of examples 1 to 9, wherein the transmission device couples the plasma source housing to the electrode by an impedance having a value in a range 0.1 ohm (e.g. 1 Ohm) to 1 Megaohm (e.g. 1 Kiloohm, e.g. 0.1 Kiloohm, e.g. 10 Ohm), for example for a frequency in a range of 1 Kilohertz (e.g. 1 Megahertz) to 100 Megahertz (e.g. 20 Megahertz) and/or the operating frequency of the plasma source.

Example 11 is configured according to one of the examples 1 to 10, wherein the transport path is arranged in a housing interior of the vacuum chamber housing, wherein the cavity is coupled to the housing interior in a fluid-conducting manner, e.g. directly adjacent to the housing interior.

Example 12 is configured according to one of examples 1 to 11, which is free of an electrode (e.g. having a grid and/or filament) arranged between the transport path and the cavity.

Example 13 is configured according to one of examples 1 to 12, further comprising: a gas separation channel having two gas separation walls between which the transport path is arranged and of which one gas separation wall provides the electrode, wherein the gas separation channel is configured to gas-separate two processing regions from each other, of which a first processing region is exposed to the plasma source and/or of which a second processing region is exposed to a coating device (e.g. sputtering device).

Example 14 is configured according to one of the examples 1 to 13, wherein the electrode is plate-shaped and/or includes a mounting device to which the RF transmission device is attached.

Example 15 is configured according to any one of examples 1 to 14, wherein an electrical impedance between the electrode and the plasma source housing provided by the transmission device is smaller for RF (e.g. at least one frequency in a range 1 MHz to 100 MHz) than an electrical impedance between the electrode and the plasma source housing provided by the vacuum chamber housing.

Example 16 is configured according to one of examples 1 to 15, wherein the transmission device is provided separately from the vacuum chamber housing and/or can be demounted therefrom.

Example 17 is arranged according to any one of examples 1 to 16 and/or is a method for operating the vacuum arrangement according to any one of examples 1 to 16, the method comprising: forming a plasma by the plasma source which is at least partially located in the cavity; and transporting a substrate by the transport device along the transport path past the plasma source (e.g. through a processing area so that the substrate is exposed to the plasma; wherein a vacuum is formed, e.g. in the cavity and/or to which the substrate is exposed (.e.g. through a processing region) so that the substrate is exposed to the plasma; wherein a vacuum is formed, e.g. in the cavity and/or to which the substrate is exposed.

Example 18 is arranged according to any one of examples 1 to 17 and/or is a method of operating the vacuum arrangement according to any one of examples 1 to 16, the method comprising: removing an additional (e.g. grid-shaped) electrode which delimits the cavity and/or is arranged between the cavity and the transport path; forming a plasma (e.g. in the cavity by the plasma source) which is preferably at least partially arranged in the cavity and to which the transport path is exposed when the additional electrode is removed (e.g. such that the plasma is at least partially arranged in the cavity).e.g. in the cavity) by the plasma source, which is preferably at least partially located in the cavity and to which the transport path is exposed when the additional electrode is removed (e.g. such that the plasma is not exposed to a grid electrode); wherein a vacuum is formed, e.g. in the cavity and/or to which the transport path is exposed.

Example 19 is arranged according to one of examples 1 to 18 and/or is a use of a wall (e.g. plate), preferably gas separation wall, which is arranged in a vacuum chamber housing, as an electrode for a plasma source which includes a plasma source housing in which a cavity is provided, the plasma source being configured to form a plasma by the cavity, the electrode being coupled ohmically to the plasma source housing by an RF transmission device. This saves installation space.

Example 20 is configured according to one of examples 1 to 19, wherein the plasma source includes a (e.g. trough-shaped or pot-shaped) protective structure (also referred to as a pot), which preferably consists of a dielectric (e.g. of glass) and/or is electrically insulating, which is arranged in the cavity, wherein the protective structure provides, for example, a recess which is arranged in the cavity.

Example 21 is configured according to one of examples 1 to 20, wherein the plasma source includes a first mounting device (e.g. a flange) (e.g. for mounting a grid electrode), which includes a mounting surface (e.g. frame-shaped and/or stepped) facing the transport path and in which an opening (which, for example, runs around from the mounting surface along a self-closed path) is formed, which opens into the cavity.

Example 22 is arranged according to any one of examples 1 to 21, wherein the plasma source housing comprises a second mounting device (e.g. an outwardly projecting flange) which encircles the cavity and/or the first mounting device along a self-closed path, wherein the second mounting device is configured to be joined to the vacuum chamber housing in a vacuum-tight manner.

Example 23 is configured according to one of examples 1 to 22, wherein the plasma source includes an electrode (also referred to as the main electrode) which is arranged in the cavity and/or delimits the cavity, wherein the plasma source preferably includes an electrical connector which is electrically coupled to the electrode. For example, the electrode can be galvanically separated from the plasma source housing.

Example 24 is arranged according to any one of examples 1 to 23, wherein an operating frequency of the plasma source for forming a plasma in the cavity is a radio frequency and/or is in a range from about 1 kilohertz (e.g. 1 MHz (megahertz)) to about 1 THz (terahertz), e.g. to about 1 GHz (gigahertz).

Example 25 is configured according to one of examples 1 to 24, wherein the RF transmission device is connected in parallel to the vacuum chamber housing.

Example 26 is arranged according to any one of examples 1 to 25, wherein the transmission device comprises one or more than one electrical conductor (e.g. the electrical RF strand, e.g., litz wire) comprising a braid comprising, for example, a plurality of filaments.

Example 27 is arranged according to any one of examples 1 to 26, wherein the RF transmission device comprises more filaments than the vacuum chamber housing and/or than the plasma source (e.g. a grid electrode thereof).

Example 28 is arranged according to any one of examples 1 to 27, wherein the RF transmission device comprises a greater proportion of copper and/or silver than the vacuum chamber housing.

Example 29 is arranged according to one of examples 1 to 28, wherein the plasma source is configured to have a grid electrode (also referred to as a protective grid) mounted thereon, which defines the cavity, the grid electrode preferably being demounted.

Example 30 is arranged according to one of examples 1 to 29, wherein the plasma source comprises a dielectric pot which is arranged in the cavity.

Example 31 is arranged according to one of examples 1 to 30, wherein the plasma source is configured to emit at least part of the plasma (e.g. as a plasma jet), e.g. (preferably in an emission direction) towards the transport path and/or out of the cavity.

Example 32 is arranged according to one of examples 1 to 31, wherein the plasma source emits at least an unneutralized part of the plasma during operation, e.g. is directed towards the transport path and/or out of the cavity.

Example 33 is configured according to one of examples 1 to 32, wherein a working gas and/or reactive gas is supplied to the cavity during operation.

Example 34 is configured according to one of examples 1 to 33, wherein the or each strand is provided by a litz wire.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary aspects of the disclosure are described with reference to the following drawings, in which:

FIGS. 1A to 5B show the vacuum arrangement in various schematic views.

### DESCRIPTION

In the following detailed description, reference is made to the accompanying drawings which form part thereof and in which specific embodiments in which the invention can be practiced are shown for illustrative purposes. In this regard, directional terminology such as “top”, “bottom”, “front”, “rear”, “front”, “rear”, etc. is used with reference to the orientation of the figure(s) described. Since components of embodiments can be positioned in a number of different orientations, the directional terminology is for illustrative purposes and is not limiting in any way. It is understood that other embodiments can be used and structural or logical changes can be made without departing from the scope of protection of the present invention. It is to be understood that the features of the various exemplary embodiments described herein can be combined with each other, unless specifically indicated otherwise. The following detailed description is therefore not to be construed in a limiting sense, and the scope of protection of the present invention is defined by the appended claims.

In the context of this description, the terms “connected”, “connected” and “coupled” are used to describe both a direct and an indirect connection (e.g. ohmic and/or electrically conductive, e.g. an electrically conductive connection), a direct or indirect connection and a direct or indirect coupling. In the figures, identical or similar elements are provided with identical reference signs where this is appropriate.

According to various embodiments, the term “coupled” or “coupling” can be understood in the sense of a (e.g. mechanical, hydrostatic, thermal and/or electrical), e.g. direct or indirect, connection and/or interaction. Several elements can, for example, be coupled together along an interaction chain along which the interaction can be exchanged, e.g. a fluid (then also referred to as fluid-conducting coupled). For example, two coupled elements can exchange an interaction with each other, e.g. a mechanical, hydrostatic, thermal and/or electrical interaction. A coupling of several vacuum components (e.g. valves, pumps, chambers, etc.) with each other can have that they are coupled with each other in a fluid-conducting manner. According to various embodiments, “coupled” can be understood in the sense of a mechanical (e.g. physical) coupling, e.g. by direct physical contact. A coupling can be set up to transmit a mechanical interaction (e.g. force, torque, etc.).

The term radio frequency (short RF or HF) is used herein to mean a frequency (e.g., high frequency) of more than 1 kHz (kilohertz), e.g. more than approximately 1 MHz (megahertz), e.g. more than approximately 1 GHz (gigahertz). In general, the value of the radio frequency is only technically limited upwards, but can be less than approximately 1000 terahertz. In this regard, exemplary reference is made herein to a frequency for operating the plasma source (also referred to as the operating frequency) of 13.56 MHz. It can be understood that what is described herein can apply to any other operating frequency, e.g. of 40 KHz, of 27.12 MHz, or of 2.45 GHz. Alternatively or additionally, the operating frequency can be in a range from about 1 Mhz to about 100 MHz.

According to various embodiments, a plasma-forming gas can be ionized by a plasma source, whereby a substrate can be processed by the plasma formed in the process. To generate a plasma, a voltage (e.g. having a radio frequency) can be applied to an electrode (also referred to as the main electrode for short) of the plasma source, for example by operating the main electrode as a cathode. Even if the voltage includes an alternating voltage, the concept of the cathode is retained.

Examples of processes that can be carried out using plasma include Ion beam assisted deposition (IBAD), plasma etching (IBE, RIBE), plasma cleaning, plasma conditioning, provision of atomic species (e.g. oxygen, nitrogen).

The plasma-forming gas can comprise, for example, one or more than one reactive gas and/or one or more than one (e.g. inert) working gas. The reactive gas can comprise a gaseous material which reacts with the substrate and/or can be incorporated into the substrate by a chemical reaction, e.g. oxygen, nitrogen, nitrogen oxides, carbon oxides and/or ozone). If, for example, a substrate is used which can form a nitride (e.g. AlNy), the reactive gas can comprise nitrogen or be formed from nitrogen. If, for example, a substrate is used that can form an oxide (e.g. AlOx), the reactive gas can contain oxygen or be formed from it. The reactive gas may, for example, comprise or be formed from a gas mixture (reactive gas mixture) of several gases which react with the substrate and/or a layer deposited thereon, e.g. oxygen and nitrogen. According to various embodiments, the reactive gas can comprise at least one of the following: Oxygen, nitrogen, hydrogen sulfide, methane, gaseous hydrocarbons, fluorine, chlorine, or another gaseous material.

According to various embodiments, the working gas can comprise a gaseous material which is inert, in other words which only participates in a few chemical reactions. A working gas may, for example, be or become defined by the substrate used and be or become adapted to it. For example, a working gas can be a gas or a gas mixture that does not react with the substrate (e.g. to form a solid). The working gas may, for example, comprise a noble gas (e.g. helium, neon, argon, krypton, xenon, radon) or several noble gases. The plasma can be formed from the working gas. The reactive gas can have a higher chemical reactivity than the working gas, e.g. with regard to the substrate

In this context, an assembly device is understood to be a device that is configured for assembly, for example for assembly on a complementary assembly device (also referred to as a counter-assembly device). Mounting involves the (e.g. rigid) connection of several components to one another by their mounting devices. The assembly can be (for example exclusively) form-fit and/or detachable. The mounting device can preferably have a (e.g. planar) mounting surface which, during mounting, rests against a complementary mounting surface of the counter-mounting device. The mounting device can, for example, have one or more than one (e.g. integral) mounting profile (e.g. form-fit profile), which is provided, for example, by an unevenness (e.g. protrusion or recess) of the mounting device. Examples of the mounting profile include: a thread, a groove (e.g. to accommodate a feather key and/or dovetail groove), a latching lug, a bayonet catch, a pin, etc. Examples of the unevenness include: an opening (e. g. through hole and/or threaded hole), a bolt (e.g. a threaded bolt)

An exemplary implementation of the mounting device is configured as a flange, e.g. as a vacuum flange. The flange can be set up for rigid and/or detachable connection to another flange. Two connected flanges form a so-called flange connection. The flange can have a (e.g. planar) mounting surface. Optionally, the flange can be penetrated by an opening (also referred to as a flange opening), which is surrounded by the mounting surface, e.g. along a closed path. The flange connection can have two flanges with their mounting surfaces facing each other, e.g. touching each other. The flange opening of a vacuum chamber housing can open into the chamber interior of the vacuum chamber housing, e.g. adjacent to it. Optionally, the flange can have a groove that surrounds the flange opening, e.g. along the closed path around the flange opening and/or adjacent to the mounting surface. The groove can optionally accommodate a seal, e.g. a metal seal or a plastic seal. Optionally, the flange can have a projection that includes the mounting surface. For example, the mounting surface can protrude.

Complex processes can require more effective gas separation than can be achieved using a chamber wall with a substrate transfer opening. For example, coating substrates with layers of different compositions (e.g. of different materials) can require different process conditions (e.g. metallic versus reactive/oxidic or different reactive gas compositions such as Ar/N₂ versus Ar/O₂) and thus an effective gas separation of the process conditions from each other, which reduces mixing of the different process conditions (gas separation).

Gas separation clearly describes a difference (e.g. gradient) in the gas pressure or in the gas composition between vacuum-connected areas (e.g. gas-separated areas). The components (e.g. the parts of a gas separation device) that contribute to gas separation can be set up in such a way that the difference in gas pressure or in gas composition between vacuum-connected areas (e.g. gas-separated areas) can be maintained (e.g. stable). In other words, gas exchange between vacuum-connected and gas-separated areas can be inhibited, e.g. the greater the gas separation between the areas.

The gas separation device (e.g. a gas separation channel) can generally implement a minimum conductance (e.g. along the transport path), i.e. that the conductance decreases along the transport path into the gas separation device and increases again along the transport path out of the gas separation device. The term “conductance” (e.g. gas conductance or general fluid conductance) of a body can be understood as a measure of its permeability for a material flow. The conductance indicates the volume of the material flow that passes through the body when it is exposed to a pressure difference (also known as pressure gradient) of the material flow. The gas conductance can be indirectly proportional to the flow resistance that the material flow experiences when passing through the body. The gas conductance of a nozzle is a function of the distance the material flow travels through the nozzle (also referred to as the length of the nozzle opening or nozzle length), the cross-sectional area of the nozzle opening and/or the shape of the nozzle opening.

According to various embodiments, the vacuum chamber can be or can be provided by a chamber housing in which one or more chambers can be or can be provided. The chamber housing can, for example, be coupled to a pump arrangement, e.g. a vacuum pump arrangement (e.g. gas-conducting), to provide a negative pressure or a vacuum (vacuum chamber housing) and can be set up in such a stable manner that it can withstand the effect of the air pressure in the pumped-down state. The pump arrangement (comprising at least one vacuum pump, e.g. a high vacuum pump, e.g. a turbomolecular pump) can make it possible to pump out part of the gas from the interior of the processing chamber, e.g. from the processing chamber. Accordingly, one or more vacuum chambers can be provided in a chamber housing. In other words, the chamber housing can be set up as a vacuum chamber housing or a coating chamber can be set up as a vacuum chamber.

As used herein, the term “vacuum pressure” means a negative pressure in the range of vacuum (i.e., a pressure of less than 0.3 bar), e.g., a pressure in a range of about 10 mbar to about 1 mbar (in other words, rough vacuum) can be provided or less, e.g. a pressure in a range from about 1 mbar to about 10⁻³ mbar (in other words fine vacuum) or less, e.g. a pressure in a range from about 10⁻³ mbar to about 10⁻⁷ mbar (in other words high vacuum) or less, e.g. a pressure of less than high vacuum, e.g. less than about 10⁻⁷ mbar.

According to various embodiments, an electrode can be electrically conductive (e.g. having an electrical conductivity of more than 10⁴ Siemens per meter) and/or metallic. For example, the electrode can comprise or consist of a metal and/or be plate-shaped.

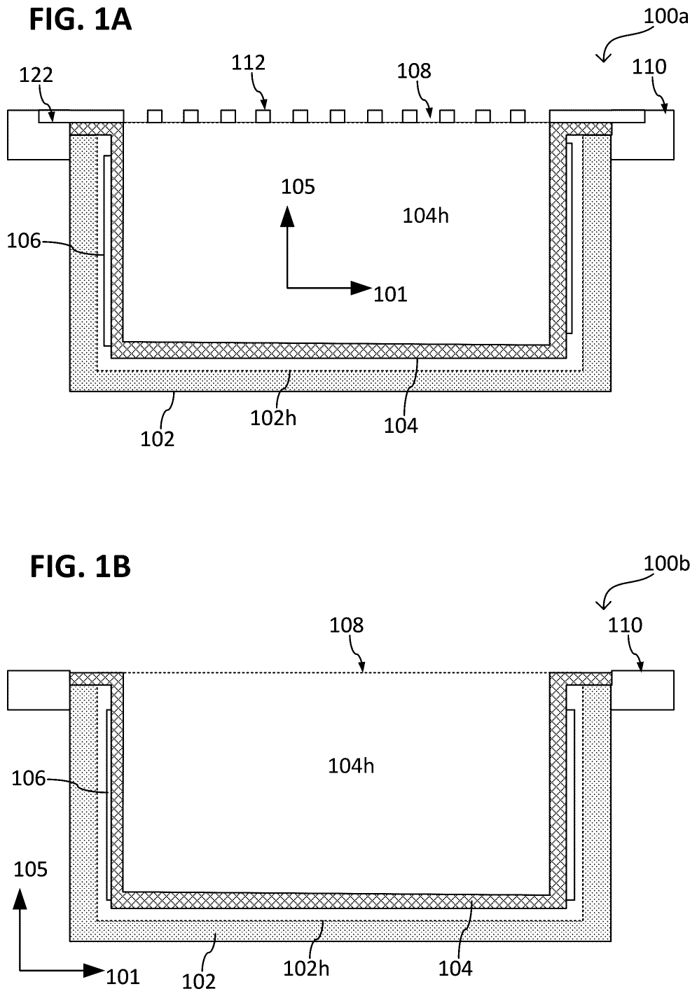

FIG. 1A illustrates a plasma source according to various embodiments 100a in a schematic side view or cross-sectional view, preferably set up according to one of Example 21 to Example 24.

An exemplary implementation for operating the plasma source comprises stimulating plasma formation in the cavity 102h (also referred to as source interior 102h) of the plasma source, e.g. the cavity 104h (also referred to as plasma forming cavity 104h) of the protective structure 104 disposed therein, to form a plasma therein. The plasma formation can be carried out by a radio frequency as operating frequency and/or by ionization of the plasma-forming gas.

An exemplary implementation of the protective structure 104 includes a glass pot which includes the plasma formation chamber 104h. Alternatively or additionally, the plasma source includes outlet opening 108, which adjoins the plasma formation chamber 104h from an emission direction 105 and/or opens into the source interior 102h.

An exemplary implementation of the plasma formation takes place by a main electrode 106, to which the operating frequency is applied during operation. The main electrode 106 may, for example, be arranged in the source interior 102h and/or arranged between the plasma source housing 102 and the protective structure 104. The operating frequency can be or can be provided by a generator (also referred to as a radio frequency generator).

An exemplary implementation of the plasma source housing 102 is attached to a vacuum flange 110, which encircles the outlet aperture 108 along a self-closed path. Alternatively or additionally, the plasma source housing 102 and/or the vacuum flange 110 have a recessed mounting surface against which the grid electrode 112 rests or at least can be mounted. The grid electrode 112 can be penetrated along the emission direction 105 by a plurality of through-holes and/or have a plurality of metallic filaments which delimit the source interior 102h. Alternatively or additionally, the grid electrode 112 can abut the protective structure 104.

An exemplary implementation of the main electrode 106 is galvanically separated from the plasma source housing 102 and/or coupled to the generator. Alternatively or additionally, the plasma source housing 102 is grounded during operation.

The plasma source can be set up as a radio frequency excited plasma beam source, e.g. as a magnetic field assisted and/or filament-less plasma beam source. The grid electrode 112 can be configured to neutralize the material passing through the grid electrode 112 (e.g., comprising portions of the plasma) during operation. If the grid electrode is mounted, the plasma source may, for example, emit a quasi-neutral plasma beam in the emission direction 105. Quasi-neutral can be understood as having on average the same number of ions as electrons.

The coupling electrical power into the plasma, which is provided by a high-frequency generator (not shown), can take place by the main electrode 106. For this purpose, a high-frequency matching network (e.g. comprising one or more than one air-core coil and/or one or more than one capacitor) can optionally be provided in order to match the impedance of the plasma source to the impedance of the high-frequency generator.

An exemplary implementation (preferably according to Example 21) of the first mounting device 122 (also referred to as a grid mounting device) is configured as a flange for mounting a grid electrode 112. It can be understood that the grid mounting device is not present when the plasma source is a grid-less plasma source. It can be understood that the grid mounting device can be disassembled when the plasma source is a gridded plasma source.

The grid mounting device 122 includes, for example, a frame-shaped recess which is delimited by a mounting surface which is directed in the emission direction 105. The mounting surface runs around the outlet opening 108 along a self-closed path.

An exemplary implementation of the second mounting device (also referred to as the housing mounting device) is provided as an outwardly cantilevered vacuum flange 110, which encircles the outlet opening 108 and/or the grid mounting device (if present) along a self-closed path. The vacuum flange 110 can have a plurality of through openings extending along the emission direction 105 for mounting the housing mounting device to the vacuum chamber housing. Furthermore, the vacuum flange 110 includes a sealing groove for receiving a sealing ring.

FIG. 1B illustrates a plasma source according to various embodiments 100b in a schematic side view or cross-sectional view, preferably set up according to one of the embodiments 100a, e.g. according to Example 21 or Example 22, wherein the grid electrode 112 is omitted or demounted (then also referred to as a grid-less plasma source).

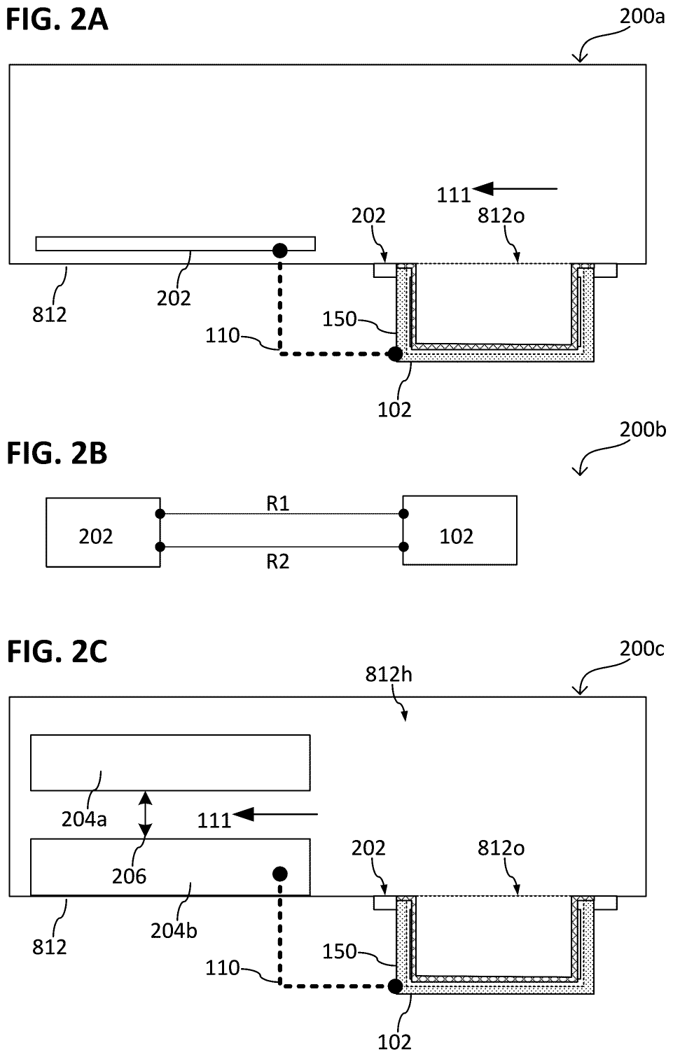

An exemplary implementation of the grid-less plasma source according to embodiments 100b is provided by removing the grid electrode 112 (also referred to as grid-shaped electrode 112) defining the cavity 104h, and mounting and/or operating without the grid electrode 112 on the vacuum chamber housing. By the grid-less plasma source thus provided according to embodiments 100b, the formation of a plasma in the plasma formation cavity 104h to which the transport path 111 is exposed occurs, for example, when a substrate is transported along the transport path 111 by the transport device (not shown). Furthermore, a wall, preferably a gas separation wall (see also FIG. 2C), which is arranged in the vacuum chamber housing 812, is used as a chamber electrode for the grid-less plasma source, in particular when the plasma is formed in the plasma formation space 104h during operation. The chamber electrode inhibits the spatial propagation of the plasma, which increases the service life of the vacuum arrangement, even if the grid electrode is mounted.

FIG. 2A illustrates a vacuum chamber arrangement 200a according to various embodiments in a schematic side view or cross-sectional view, preferably set up according to one of the embodiments 100a to 100b and/or according to example 2.

An exemplary implementation of the vacuum chamber housing 812 includes a vacuum flange 202 to which the plasma source 150, e.g. its vacuum flange, is mounted. Furthermore, the vacuum chamber housing 812 includes a chamber opening 812o, to which the plasma source, e.g. its outlet opening 108, is adjacent. The chamber opening opens into the interior of the vacuum chamber housing 812 (also referred to as the housing interior). The transport path 111 can be arranged in the interior of the vacuum chamber housing 812.

An exemplary implementation of the chamber electrode 202 is disposed adjacent to the chamber opening 812o and/or is plate-shaped. The chamber electrode 202 further contacts a wall of the vacuum chamber housing 812 (also referred to as the housing wall) in a contacting manner.

An exemplary implementation of the radio frequency transmission device 110 (also referred to as the RF transmission device 110) couples the chamber electrode 202 to the plasma source housing 102, e.g., connected in parallel with the vacuum chamber housing 812. Alternatively or additionally, the RF transmission device 110 extends through a through opening in the vacuum chamber housing 812.

Illustratively, the RF transmission device 110 reduces the impedance between the chamber electrode 202 and the plasma source housing 102. Therefore, the RF transmission device 110 and/or the chamber electrode 202 need not necessarily be electrically isolated from the plasma source housing 102, but can optionally be ohmically coupled thereto.

FIG. 2B illustrates a vacuum arrangement according to various embodiments 200b in a schematic diagram as an equivalent circuit diagram, preferably set up according to one of the embodiments 100a to 200a and/or example 10.

The vacuum arrangement can implement a plurality of current paths that couple the chamber electrode 202 to plasma source housing in parallel with each other, a first current path of which is implemented by the plasma source housing 102 and includes a first impedance R1, and a second current path of which is implemented by the transmission device 110 and includes a second impedance R2. The first impedance and the second impedance can satisfy the following relation, e.g. for a radio frequency (e.g. the operating frequency): R2<R1, e.g. R1=10^{(k})·R2, where k≥0 (e.g. k≥1, k≥2, k≥3 or k≥4) and/or k≤10.

FIG. 2C illustrates a vacuum arrangement according to various embodiments 200c in a schematic equivalent circuit diagram, preferably set up according to one of embodiments 100a to 200b and/or example 13.

An exemplary implementation of the gas separation channel (also referred to as a channel-shaped gas separation device) includes two plate-shaped gas separation walls 204a, 204b, between which a gas separation gap 206 (illustratively a constriction) is formed, through which the transport path 111 extends. The gas separation gap 206 can separate two regions of the chamber interior 812h of the vacuum chamber housing 812 from each other. One or more than one of the two gas separation walls 204a, 204b can be coupled to the plasma source housing 102 as a chamber electrode 202 by a transmission device 110 and thus be operated as a chamber electrode.

An exemplary implementation of the vacuum arrangement includes two gas separation channels, between which a vacuum region is arranged, to which a processing device (e.g. having the plasma source and optionally a coating device) is adjacent (also referred to as the processing region). For example, the vacuum arrangement can have two processing areas between which the gas separation channel is arranged and into which the gas separation gap 206 opens.

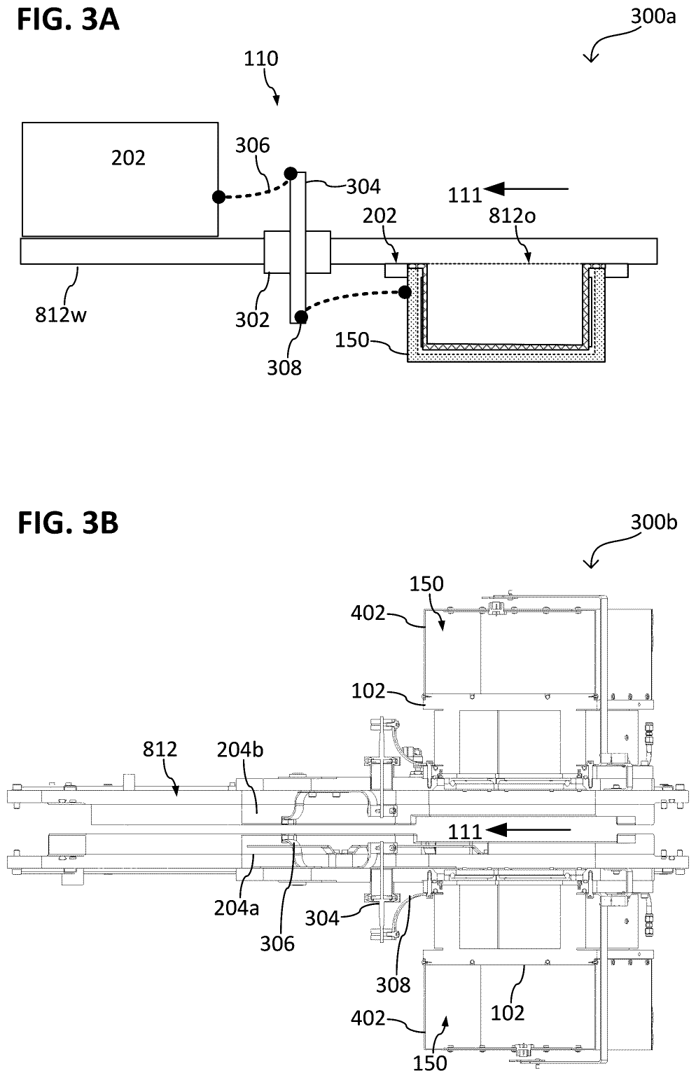

FIG. 3A illustrates a vacuum chamber arrangement 300a according to various embodiments in a schematic side view or cross-sectional view, preferably set up according to one of embodiments 100a to 200b and/or according to example 6 or example 7.

An exemplary implementation of the transmission device 110 (preferably according to Example 7 and/or Example 9) comprises a copper rod 304 held by a vacuum feedthrough 302 disposed in a through opening (also referred to as a wall opening) of the vacuum chamber housing 812 (e.g., a chamber wall 812w thereof). The copper rod 304 can extend through the vacuum passageway 302 and/or the chamber wall 812w thereof. Further, the transmission device 110 includes two radio frequency (RF) strands (e.g., connected in series) which are coupled together by the copper rod 304 and of which a first RF strand 306 (e.g., litz wire) is connected between the chamber electrode 202 and the copper rod 304, and of which a second RF strand 308 (e.g., litz wire) is connected between the plasma source housing 102 and the copper rod 304.

An exemplary implementation of the RF stranded wire includes a plurality of metallic filaments (e.g. made of copper), each filament of which is optionally coated, e.g. with a dielectric (e.g. a dielectric polymer) and/or with silver. Each filament can, for example, consist of a copper wire. The number N of filaments per RF strand can be, for example, N≥10^{k}, where k≥0 (e.g. k≥1, k≥2, k≥3 or k≥4) and/or k≤10. The greater N, the lower the impedance of the RF strand (e.g., litz wire). The plurality of filaments is also braided or twisted together, which reduces the impedance of the RF strand.

An electric current flow at radio frequency essentially only flows on the surface of the filaments. For example, at a frequency of 10 MHz, the current density 20 μm below the surface is less than 37% of the current density on the outermost surface.

FIG. 3B illustrates a vacuum arrangement according to various embodiments 300b in a schematic equivalent circuit diagram, preferably set up according to one of the embodiments 100a to 300a and/or according to example 6 or example 7.

An exemplary implementation of the vacuum arrangement includes a plurality of assemblies, for example two assemblies between which the transport path 111 is arranged, each assembly comprising:
a plasma source 150;
a gas partition 204a, 204b, which is configured as a chamber electrode 202;
an RF transmission device 110, which is connected between the plasma source housing 102 of the plasma source 150 and the gas partition 204a, e.g. in parallel with the vacuum chamber housing 812.

An exemplary implementation of the plasma source 150 includes an electrical generator 402, which is configured to generate the operating frequency and supply it to the main electrode 106. The generator 402 is coupled to the plasma source housing 102, for example attached thereto, which enables a compact design.

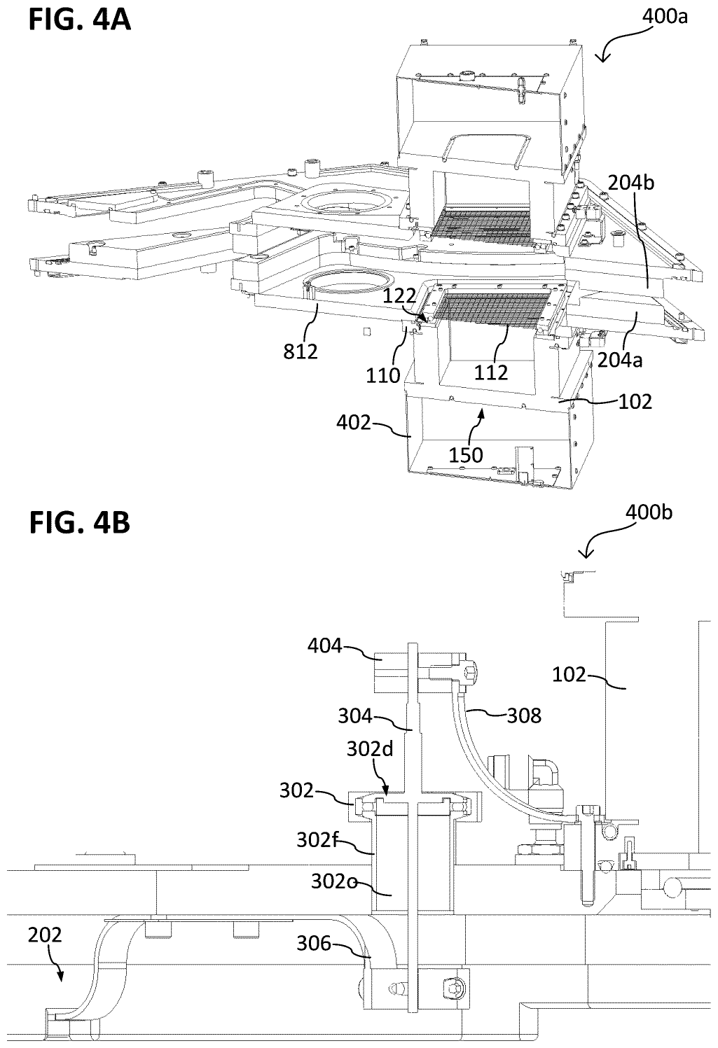

FIG. 4A illustrates a vacuum chamber arrangement 400a according to various embodiments in a schematic sectional perspective view, preferably arranged according to any one of embodiments 100a to 300b and/or according to Example 6 or Example 7. As explained herein, the grid electrode 112 can be or can be disassembled so as to provide a grid-less plasma source.

FIG. 4B illustrates a vacuum arrangement according to various embodiments 400b in a schematic detailed view of the coupling device 110, preferably set up according to one of embodiments 100a to 400a and/or according to example 6 or example 7.

An exemplary implementation of the vacuum feedthrough 302 includes a flange 302f, which is penetrated by the wall opening 302o and/or which is sealed with a cover 302d. The cover 302d is monolithically connected to the copper rod 304.

An exemplary implementation of the transmission device 110 includes, per RF wire 306, a screw coupling 404, by which the RF wire 306 is coupled to the copper rod 304.

An exemplary implementation of the RF strand 306 is configured as a flat strand (e.g., litz wire).

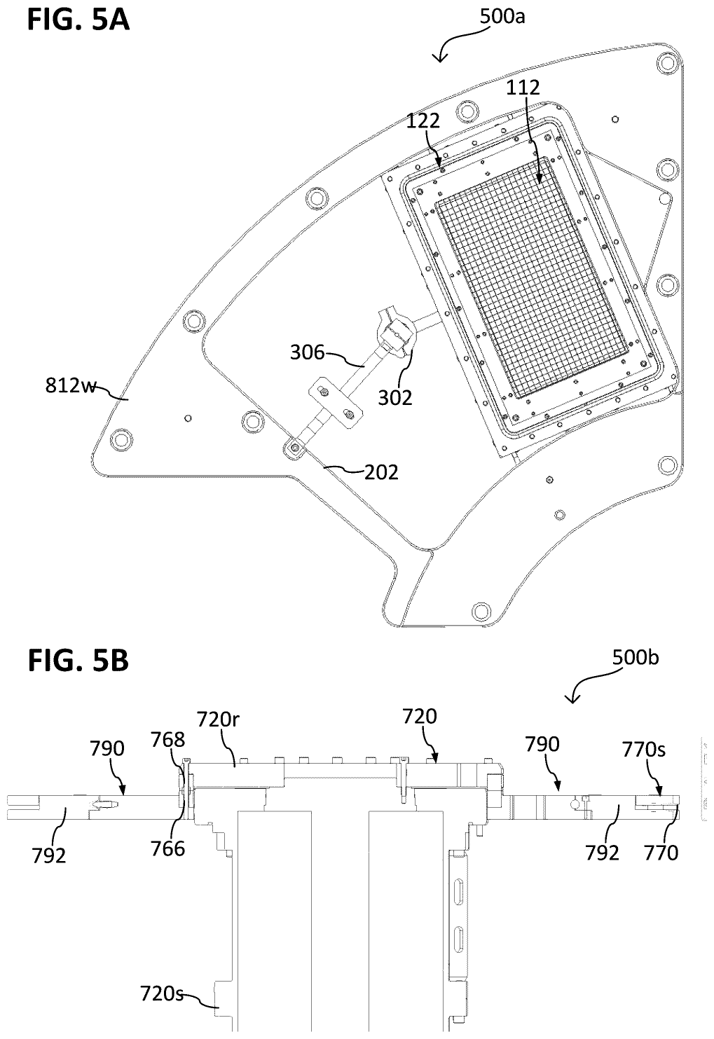

FIG. 5A illustrates a vacuum chamber arrangement 500a according to various embodiments in a schematic sectional plan view from the transport path, preferably set up according to any one of embodiments 100a to 400b and/or according to Example 21 and/or Example 22. It can be understood that the grid electrode 112 can be disassembled and/or omitted during operation of the plasma source.

An exemplary implementation of the grid electrode 112 includes a frame-like structure penetrated by a through-hole, and a plurality of filaments forming a grid disposed in the through-hole.

FIG. 5B illustrates a vacuum arrangement according to various embodiments 500b in a schematic sectional detail view of the transport device, preferably set up according to one of the embodiments 100a to 400b and/or according to example 2.

An exemplary implementation of the transport device is configured as a turntable transport device, which includes a plate-shaped substrate carrier (also referred to as a turntable) for transporting a substrate along a circular transport path. The turntable includes several sections, each section of which is arranged in a receiving gap 770. Furthermore, the transport device, e.g. its substrate carrier holding device 790, includes a mounting base 792 per section, which provides the receiving gap 770. The transport device includes, for example, several substrate carrier segments (not shown), which provide the turntable.

An exemplary implementation of the turntable is configured as a multi-part turntable, the substrate carrier segments 780 of which are circular ring segment-shaped (for example in the form of cake pieces). The transport device includes a rotor 720r with which, for each substrate carrier segment, a mounting base 792 with clamping jaw 770s, which forms the receiving gap 770, is coupled for mounting and aligning the substrate carrier segment. The mounting base 792 can, for example, be rotatably mounted, for example by a swivel joint having a shaft. The swivel joint makes it easier to tilt and/or lift the substrate carrier, or more generally speaking, to align it. Furthermore, additional screws can be provided to lock the resulting position of the swivel joint.

An exemplary implementation of the substrate carrier, for example the turntable, is arranged in and/or transported through the gas separation gap 206.

An exemplary implementation of the substrate carrier holding device 790 includes a first ring 766, which includes a plurality of teeth for forming a Hirth toothing. Complementary thereto, the rotor, e.g. its hub, includes a second ring 768 (also referred to as a toothed ring), which includes a plurality of teeth for forming the Hirth serration.

An exemplary implementation of the rotor is provided by a rotary union 720, the stator 720s of which is attached to the vacuum chamber housing 712 (e.g. by screws) and the rotor 720r of which is attached to the substrate carrier holding device 790 (e.g. by screws). Optionally, the substrate carrier holding device 790 can be coupled to the rotor 720r by the Hirth coupling, which facilitates centering and imparting a torque.

During operation, one substrate can be transported using the substrate carrier, e.g. per substrate carrier segment.

It can be understood that the aspects explained herein can also be used in a continuous flow system whose transport device includes several transport rollers arranged one behind the other along the transport path.

Various examples of work are described below, which relate to what is described above and shown in the figures.

In working example 1, the grid electrode of the plasma source is omitted and/or demounted during operation, e.g. when forming the plasma in the plasma formation chamber. The grid mounting device can then be exposed, e.g. exposed to the plasma. This increases the service life, reduces costs and increases ease of maintenance.

In working example 2, the grid electrode of the plasma source is functionally replaced by an RF capacitor, which includes the chamber electrode and is configured to limit the spatial spread of the plasma near the plasma source. This prevents the RF field from leaving the plasma formation area and thereby propagating the plasma when the grid electrode is omitted and/or demounted.

In working example 3, a grounded gas separation plate is provided as a gas separation wall, which is ohmically coupled to the housing of the plasma source via a stranded wire (e.g., litz wire) that provides plenty of surface area to transmit RF. The litz wire is configured as an RF transmitter.

In working example 4, an electrical vacuum feed-through (at least by a copper rod) is provided to connect two sections of stranded wire together.

In working example 5, a defined coupling and decoupling of the RF field is provided in the coating system, which also inhibits parasitic plasma formation.

1. A vacuum arrangement comprising:
a vacuum chamber housing;
a transport device for transporting a substrate along a transport path within the vacuum chamber housing;
a plasma source comprising a plasma source housing in which a cavity is provided, wherein the plasma source is configured to form, by the cavity, a plasma to which the transport path is exposed;
an electrode disposed in the vacuum chamber housing beside the plasma source; and
a radio frequency transmission device that ohmically couples the plasma source housing to the electrode.

2. The vacuum arrangement according to claim 1, wherein the radio frequency transmission device comprises one or more electric lines provided by a radio frequency strand.

3. The vacuum arrangement according to claim 2, wherein the radio frequency strand comprises a plurality of filaments.

4. The vacuum arrangement according to claim 3, wherein the plurality of filaments are coated with a dielectric.

5. The vacuum arrangement according to claim 3, wherein the plurality of filaments are braided or twisted.

6. The vacuum arrangement according to claim 1, wherein the radio frequency transmission device comprises a first line arranged in the vacuum chamber housing and is provided by a radio frequency strand.

7. The vacuum arrangement according to claim 1, wherein the radio frequency transmission device comprises a second electrical line arranged outside the vacuum chamber housing and is provided by a radio frequency strand.

8. The vacuum arrangement according to claim 1, wherein the radio frequency transmission device couples the plasma source housing to the electrode by an impedance having a value ranging from 0.1 ohm to 1 Kiloohm for a frequency ranging from 1 Kilohertz to 100 Megahertz.

9. The vacuum arrangement according to claim 1, wherein the vacuum chamber housing comprises a housing opening in which a vacuum feedthrough of the transmission device is arranged.

10. Vacuum arrangement according to claim 9, wherein the vacuum feedthrough comprises a copper rod.

11. The vacuum arrangement according to claim 10, wherein the copper rod extends through the housing opening.

12. The vacuum arrangement according to claim 10, wherein the copper rod ohmically couples two radio frequency strands of the transmission device to each other.

13. The vacuum arrangement according to claim 1, wherein the plasma source comprises a first mounting device comprising a mounting surface facing the transport path for mounting a grid electrode, wherein an opening, which is formed in the mounting surface, joins the cavity.

14. The vacuum arrangement according to claim 1, wherein the plasma source housing comprises a second mounting device providing an outwardly projecting flange, which encircles the cavity, wherein the second mounting device is configured to be joined to the vacuum chamber housing in a vacuum-tight manner.

15. The vacuum arrangement according to claim 1, wherein the plasma source comprises an electrode disposed in the cavity, the electrode being galvanically separated from the plasma source housing.

16. A vacuum arrangement according to claim 1, further comprising:
a gas separation channel comprising two gas separation walls between which the transport path is disposed, and of which one gas separation wall provides the electrode.

17. The vacuum device according to claim 1, wherein an electrical impedance between the electrode and the plasma source housing provided by the transmission device is smaller for a radio frequency than an electrical impedance between the electrode and the plasma source housing provided by the vacuum chamber housing.

18. The vacuum arrangement according to claim 1, wherein the radio frequency transmission device is provided separately from the vacuum chamber housing.

19. A method of operating the vacuum assembly according to claim 1, the method comprising:
removing a grid electrode, which delimits the cavity; and
forming a plasma in the cavity by the plasma source when the grid electrode is removed.

20. A vacuum arrangement comprising:
a vacuum chamber housing;
a transport device for transporting a substrate along a transport path within the vacuum chamber housing;
a plasma source comprising a plasma source housing in which a cavity is provided, wherein the plasma source is configured to form, by the cavity, a plasma to which the transport path is exposed;
an electrode disposed in the vacuum chamber housing beside the plasma source;
a first litz wire ohmically coupled to the plasma source housing;
a second litz wire ohmically coupled to the electrode;
wherein the vacuum chamber housing comprises a housing opening in which a vacuum feedthrough is arranged, which ohmically couples the first litz wire to the second litz wire.
